(19) United States
(12) Patent Application Publication
(10) Pub. No.: US 2009/0008655 A1
(43) Pub. Date: Jan. 8, 2009

(54) White Light Source

(75) Inventors: Martinus Petrus Joseph Peeters, Eindhoven (NL); Johannes Petrus Maria Ansems, Eindhoven (NL); Peter Hubertus Deurenberg, Eindhoven (NL)

Correspondence Address: PHILIPS INTELLECTUAL PROPERTY & STANDARDS, 3 BURLINGTON WOODS DRIVE, BURLINGTON, MA, 01803, US

(73) Assignee: KONINKLIJKE PHILIPS ELECTRONICS N.V., Eindhoven (NL)

(21) Appl. No.: 12/162,349

(22) PCT Filed: Jan. 25, 2007
(86) PCT No.: PCT/IB07/50251

§ 371 Date: Jul. 26, 2008

(30) Foreign Application Priority Data
Jan. 31, 2006 (EP) 06101061.7

(51) Int. Cl. H01L 33/00

(52) U.S. Cl. 257/89; 257/E33.061

(57) ABSTRACT

A white light source (1) comprising an array of at least one blue light source (2), at least one green light source (3), and at least one red light source (4) is disclosed. The blue light source (2) comprises a first light emitting diode (2′) capable of emitting light at a first wavelength. A first wavelength-converting material (2″) is arranged to absorb at least a portion of the light of the first wavelength, and the first wavelength-converting material (2″) is capable of emitting light at a second wavelength, which is at least 500 nm.

The present invention relates to a white light source comprising an array of at least one blue light source, at least one green light source, and at least one red light source. The blue light source comprises a first light emitting diode capable of emitting light at a first wavelength. A first wavelength-converting material is arranged to absorb at least a portion of the light of the first wavelength, and the first wavelength-converting material is capable of emitting light at a second wavelength.

Different approaches may be used to generate white light using LEDs. One approach is to mix yellow and blue colours, in which case the yellow component of the output light may be provided by a yellow phosphor and the blue component may be provided by the primary emission of the blue LED. This is referred to as the dichromatic approach.

Another approach is to employ a combination of blue, red and green LEDs, which is also referred to as the trichromatic approach, or the RGB approach. The LEDs may be provided as chips, also referred to as dices. The blue LEDs may be intrinsic blue LEDs or phosphor-converted UV diodes. The red and green LEDs may be intrinsic red and green LED dices, or the red and green channel can be equipped with blue LEDs, that via phosphor conversion yield the desired red and green colour, respectively.

A white light source using the principle of RGB mixing is described e.g. in U.S. Pat. No. 6,799,865 B2, where the radiation of UV diodes is converted by means of phosphors which emit in the red and green spectral regions. The blue component is added by blue-emitting LEDs.

In order to make white light with a low Correlated Colour Temperature (“CCT”, which is defined as the absolute temperature of a black body whose chromaticity most nearly resembles that of the light source), e.g. 2700 K, the amount of blue light leaking through the phosphor layers on the red and green channel must be very low (<10% in power). Using scattering phosphor layers, this results in a low efficiency, see FIG. 2. (In FIG. 2, PS3504, NP002, and NP003 relates to the phosphor batch, which in all cases was a (Ba_{0.75}Sr_{0.25})₂Si₅N₈ (red) phosphor. S184 and OCK451 relates to the matrix materials; Si184=Sylgard-184 (Dow Corning) with a refractive index of 1.4, and OCK4-51 is a silicon gel obtained from Nye optical with a refractive index of 1.51.)

When trying to make colour temperature variable white light, this yields a very unfavourable situation (low efficiency). Moreover, the power dissipated in the blue channel (in a 4-2-1 RGB module) is maximal 30% for white light with a colour temperature of 4000 K.

There is thus a continuing need for improved white light devices.

It is an object of the present invention to overcome the above-identified problems, and to provide a colour temperature variable white light source. This is obtained by a white light source (1) comprising an array of at least one blue light source (2); at least one green light source (3); and at least one red light source (4). The blue light source (2) comprises a first light emitting diode (2′) capable of emitting light at a first wavelength, and a first wavelength-converting material (2″) arranged to absorb at least a portion of said light of said first wavelength. The first wavelength-converting material (2″) is capable of emitting light at a second wavelength, which is at least 500 nm. In particular, the second wavelength lies in the range of 590 nm to 750 nm.

By a white light source according to the present invention, the blue light is converted to red at very low losses. For prior art devices, the decrease of the efficiency with increasing degree of conversion is much larger than would be expected on the basis of the Stokes shift (compare the efficiency at x=0.6 with the efficiency at x=0.35 in FIG. 2). It is therefore more favourable to make some red (or green) light using the blue LED, using partial conversion by a thin phosphor layer.

Further, the amount of electrical power that can be dissipated in the module increases, since better use of the blue channel(s) can be made. Another advantage is that the module will show a better colour homogeneity.

The portion of light at the first wavelength absorbed by the first wavelength-converting material constitutes in the range of 10%-70% of a total amount of emitted light at said first wavelength, in particular in the range of 45%-55%.

The first wavelength may lie in the range of 400 nm to 485 nm.

The first wavelength-converting material (2″) may be disposed as a uniform layer over said first light emitting diode (2′), e.g. in a thickness in the range of 1 to 10 μm. Non-exhaustive examples of first wavelength-converting materials (2″) to be used in the present invention are YO₂S:Eu³⁺, Bi³⁺; YVO₄:Eu³⁺, Bi³⁺; SrS:Eu²⁺; SrY₂S₄:Eu²⁺; CaLa₂S₄:Ce³⁺; ZnCdS:Ag,Cl; (Ca,Sr)S:Eu²⁺; (Ca,Sr)Se:Eu²⁺; SrSi₅N₈:Eu²⁺; (Ba_{1-x-y}SrₓCa_{y})₂Si₅N₈:Eu²⁺; and/or (Sr_{1-x-y}CaₓBa_{y})₂Si₅₋ₓAlₓN₈₋ₓO:Eu, where 0≦x≦1, 0≦y≦1, and 0≦(x+y)≦1.

The green light source (3) may comprise a second light emitting diode (3′) capable of emitting light at a third wavelength, and a second wavelength-converting material (3″) arranged to absorb at least a portion of said light at said third wavelength. The second wavelength-converting material (3″) is capable of emitting light at a fourth wavelength.

The third wavelength may e.g. lie in the range of 380 nm to 485 nm.

The fourth wavelength may e.g. lie in the range of 500 to less than 590 nm.

The portion of light at the third wavelength absorbed by the second wavelength-converting material (3″) constitutes at least 90% of a total amount of emitted light at said third wavelength. The second wavelength-converting material (3″) may be disposed as a uniform layer over said second light emitting diode, e.g. in a thickness in the range of 5 to 40 μm. Non-exhaustive examples of second wavelength-converting materials (3″) for use in the present invention are ZnS:Cu,Ag; SrSi₂O₂N₂:Eu²⁺; (Sr₁₋ᵤ₋ᵥ₋ₓMgᵤCaᵥBaₓ)(Ga_{2-y-z}Al_{y}In_{z}S₄):Eu²⁺; SrGa₂S₄:Eu²⁺; (Ba₁₋ₓSrₓ)SiO₄ Eu; (Ba,Sr,Ca)SiO₄:Eu²; and/or YAG phosphors, where 0≦(u,v,x,y,z)≦1, 0≦(y+z)≦1, and 0≦(u+v+x)≦1.

The red light source (4) may comprise a third light emitting diode (4′) capable of emitting light at a fifth wavelength, and a third wavelength-converting material (4″) arranged to absorb at least a portion of said light at said fifth wavelength. The third wavelength-converting material (4″) is capable of emitting light at a sixth wavelength.

The fifth wavelength may lie in the range of 380 nm to 485 nm.

The sixth wavelength may lie in the range of 590 nm to 750 nm.

The portion of light at the fifth wavelength absorbed by the third wavelength-converting material (4″) constitutes at least 90% of a total amount of emitted light at the fifth wavelength. The third wavelength-converting material (4″) may be disposed as a uniform layer over said third light emitting diode (4′), e.g. in a thickness in the range of 5 to 40 μm. Non-exhaustive examples of third wavelength-converting materials (4″) are YO₂S:Eu³, Bi³⁺; YVO₄:Eu³, Bi³⁺; SrS:Eu²; SrY₂S₄:Eu²; CaLa₂S₄:Ce³; ZnCdS:Ag,Cl; (Ca,Sr)S:Eu³⁺; (Ca,Sr)Se:Eu²; SrSi₅N₈:Eu²; (Ba_{1-x-y}SrₓCa_{y})₂Si₅N₈:Eu²⁺; (Sr_{1-x-y}CaₓBa_{y})₂Si₅₋ₓAlₓN₈₋ₓOₓ:Eu; YO₂S₂:Eu; and/or SrY₂S₄:Eu², where 0≦x≦1, 0≦y≦1, and 0≦(x+y)≦1.

Alternatively, the green light source (3) may comprise a light emitting diode-emitting light at a wavelength in the range of 500 to less than 590 nm, and the red light source may comprise a light emitting diode-emitting light at a wavelength in the range of 590 nm to 750 nm.

A white light source (1) according to the invention may comprise one blue light source (2), two green light sources (3) and four red light sources (4), in which case the light source (1) is capable of emitting white light having a colour temperature of 2700 K. A white light source (1) according to the invention may also comprise two blue light sources (2), two green light sources (3) and three red light sources (4), in which case the light source (1) is capable of emitting white light having a colour temperature of 4000 K. However, it should be noted that white light sources according to the invention are capable of emitting a range of white light with variable colour temperature, depending on the drive current through the individual colour channels.

The present invention also relates to a light-emitting device comprising a white light-emitting source as described above.

These and other aspects of the present invention will now be described in more detail with reference to the appended drawings showing a currently preferred embodiment of the invention.

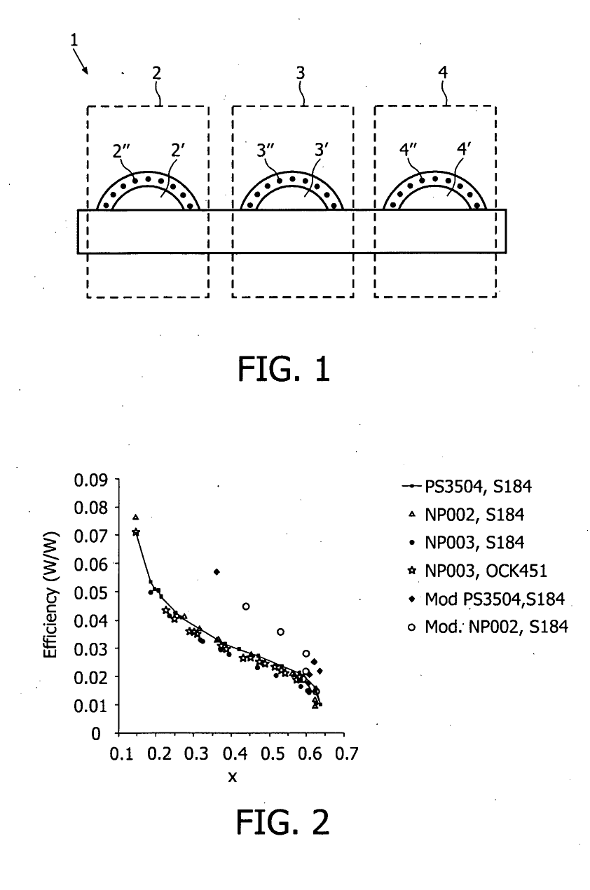

FIG. 1 shows a white light-emitting source according to the invention.

FIG. 2 shows the efficiency (watts radiative power/electrical input power) as a function of colour coordinate X.

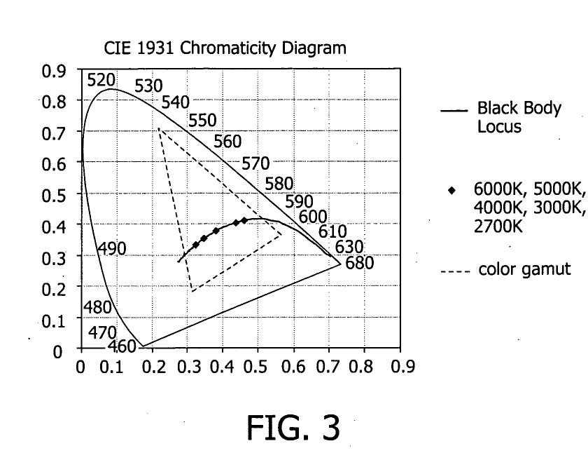

FIG. 3 shows the colour gamut, i.e. the range of possible attainable colours, of a light source according to the invention.

The present inventors surprisingly found that the conversion of about 50% of the blue LED power to red (using a phosphor) in a trichromatic (RGB) white light source results in a colour temperature variable module with an increased efficiency.

Generally described, the present invention suggests that the blue light source in an RGB white light source comprises a LED emitting light at a first wavelength, preferably in the range of 400-485 nm, i.e. in the blue region, and that a portion of this light is absorbed by a first wavelength-converting material which converts the absorbed light to a second wavelength, preferably in the range of 590 to 750 nm, i.e. in the red region. This results in an increase of the efficiency and more efficient use of the LEDs. The wavelength indicated corresponds with the peak wavelength of the wavelength-converting material.

It is also to be understood that “the second wavelength” not necessarily lies within the red region. The essence of the invention is that a part of the light emitted by the LED in the blue light source is converted to a wavelength outside the blue region, i.e. having a wavelength of at least 500 nm.

The portion of light absorbed by the first wavelength-converting material may be in the range of 10% to 70% of the total amount emitted, e.g. in the range of 45% to 55%, preferably about 50%. A lower portion of the total amount emitted will lead to a larger colour gamut. The efficiency gain will, however, be lower.

The percentage of absorbed light is preferably adjusted by varying the thickness of the layer of the first wavelength-converting material. The thickness of the layer of the first wavelength-converting material may e.g. be in the range of 1 to 10 μm and is preferably 5 μm or less. The thickness depends on the scattering properties of the phosphor mixture. The use of less scattering mixtures (i.e. smaller phosphor powders or higher refractive index of the matrix) will lead to larger layer thicknesses.

Examples of wavelength-converting materials converting blue light to red light are YO₂S:Eu³⁺, Bi³⁺; YVO₄:Eu³⁺, Bi³⁺; SrS:Eu²⁺; SrY₂S₄:Eu²⁺; CaLa₂S₄:Ce³⁺; ZnCdS:Ag,Cl; (Ca,Sr)S:Eu²⁺; (Ca,Sr)Se:Eu²⁺; SrSi₅N₈:Eu²⁺; (Ba_{1-x-y}SrₓCa_{y})₂Si₅N₈:Eu²⁺; and (Sr_{1-x-y}CaₓBa_{y})₂Si₅₋ₓAlₓN₈₋ₓOₓ:Eu.

The green light source and the red light source in a white light source according to the invention may be constructed in conventional ways, either by using blue LEDs and/or UV LEDs and wavelength-converters, or by using intrinsically red and/or green LEDs. It is to be noted, however, that the combination of such conventional red and/or green LEDs with the above-described (partially converted) blue LEDs has not been previously described.

As used herein, “a light source” refers to a light-emitting unit, for example a light emitting diode (LED). The LEDs may be provided as chips, also referred to as dices. In the context of the present invention, “the white light source” relates to an array of LEDs of different colours.

As used herein, “a wavelength-converting material” relates to a material which has the ability to convert one (monochromatic) wavelength into another wavelength, thus changing the colour of the light emitted. A wavelength-converting material is commonly referred to as a phosphor.

With reference to FIG. 1, a preferred white light source (1) according to the invention comprises an array of at least a blue light source (2), at least a green light source (3), and at least a red light source (4). Each light source is a separately addressable entity, i.e. each light source can be controlled independently of the others.

The blue light source (2) comprises a blue LED (2′), and a phosphor layer, (2″) disposed over the LED (2′). The phosphor layer (2″) could either be in direct contact with the LED (2′), or there could be an airgap between the LED (2′) and the phosphor layer (2). The phosphor layer (2″) could be disposed over the whole accessible surface of the LED (2′) or over a part of the surface of the LED (2′). Preferably, the complete dye is covered with a phosphor layer of half the thickness instead of half the dye with a thick phosphor layer. Also for colour mixing the first situation is preferred.

The blue LED (2′) emits blue light, and the phosphor layer (2″) absorbs about 50% of the total amount of emitted blue light and converts it to red light. Thus, the light emitted from the blue light source (2) is a mix of blue and red light.

The green light source (3) may comprise a blue LED (3′), and a green phosphor (3″) converting blue light to green light. Alternatively, the green light source (3) may comprise an intrinsically green LED (not shown).

Examples of green phosphors (3″) converting blue light to green light are ZnS:Cu,Ag; SrSi₂O₂N₂:Eu²⁺; (Sr₁₋ᵤ₋ᵥ₋ₓMgᵤCaᵥBaₓ)(Ga_{2-y-z}Al_{y}In_{z}S₄):Eu²⁺; SrGa₂S₄:Eu²⁺; and (Ba₁₋ₓSrₓ)SiO₄:Eu, where 0≦(u,v,x,y,z)≦1, 0≦(y+z)≦1, and 0≦(u+v+x)≦1. In addition, YAG phosphors, in particular (Y, Gd)₃(Al,Ga)₅O₁₂, Ce, may be used as green phosphors.

Examples of green phosphors (3″) converting UV-light to green light are ZnS:Cu,Ag; and (Ba,Sr,Ca)SiO₄:Eu². Other examples of green phosphors (4″) converting UV-light to green light are disclosed in WO 2005/083036 on page 12.

The thickness of the green phosphor (3″) may e.g. be in the range of 5 to 40 μm. However, the thickness of the phosphor is strongly depended on scattering properties of the phosphor mixture. The important criterion is that the blue leakage is smaller than 10 percent.

The red light source (4) may comprise a red LED (4′), and a red phosphor (4″) converting blue light to red light. Alternatively, the red light source (4) may comprise an intrinsically red LED (not shown).

Examples of red phosphors (4″) converting blue light to red light are YO₂S:Eu³⁺, Bi³⁺; YVO₄:Eu³, Bi³⁺; SrS:Eu²⁺; SrY₂S₄:Eu²⁺; CaLa₂S₄:Ce³⁺; ZnCdS:Ag,Cl; (Ca,Sr)S:Eu²⁺; (Ca,Sr)Se:Eu²⁺; SrSi₅N₈:Eu²⁺; (Ba_{1-x-y}SrₓCa_{y})₂Si₅N₈:Eu²⁺; and (Sr_{1-x-y}CaₓBa_{y})₂Si₅₋ₓAlₓN₈₋ₓOₓ:Eu, where 0≦x≦1, 0≦y≦1, and 0≦(x+y)≦1.

Examples of red phosphors (4″) converting UV-light to red light are YO₂S₂:Eu; and SrY₂S₄:Eu². Other examples of red phosphors (4″) converting UV-light to red light are disclosed in WO 2005/083036 on page 13.

The thickness of the red phosphor (4″) may e.g. be in the range of 5 to 40 μm. However, the thickness of the phosphor is strongly depended on scattering properties of the phosphor mixture. The important criterion is that the UV leakage is small. Leakage of UV-light will not influence the colour gamut of the device, it will, however, result in a low efficiency.

Consequently, the LEDs (2′, 3′, and 4′) may be of the same type, i.e. blue LEDs, and the different colours may be obtained by phosphor conversion. It is to be noted that each LED (2′, 3′, and 4′) is a separate entity, which provides for applying different phosphors to different LEDs (2′, 3′, and 4′). The individual LEDs (2′, 3′, and 4′) are then arranged in arrays in order to obtain a completed white light source.

The individual LEDs may be arranged in several configurations according to the invention, e.g. in a 4-2-1 RGB configuration (i.e. 4 red LEDs, 2 green LEDs and 1 blue LED). Other examples of suitable configurations are 3-3-1 configuration, 4-4-1 configuration or 3-2-2 configuration (in which two of the blue dices are partially converted).

FIG. 3 shows the colour gamut, i.e. the range of possible attainable colours of a light source according to the invention. The CIE chromaticity diagram is a well-known standard reference for defining colours, and as a reference for other colour spaces. The CIE chromaticity diagram contains the Black Body Locus (“BBL”), represented by the continuous line in FIG. 3. The chromaticity coordinates (i.e. colour points) that lie along the BBL obey Planck's equation: E(λ)=Aλ⁻⁵/(e^{(B/T)}−1), where E is the emission intensity, λ is the emission wavelength, T the colour temperature of the black body and A and B are constants. Various values of the colour temperature, T, in degrees Kelvin are shown on the BBL in FIG. 3.

Typical white light illumination sources are chosen to have chromaticity points on the BBL with colour temperatures in the range between 2500 K to 7000 K. In FIG. 3, five points on the BBL are shown, from left to right: 6000K, 5000K, 4000K, 3000K and 2700K. Points or colour coordinates that lie away from the BBL are less acceptable as white light.

The white light source according to the invention could be used in all kinds of LEDs for general lighting, especially spot applications.

An RGB module was prepared with the following design: 1 blue, 2 green and 4 red dices; Green: intrinsic LED, Red: phosphor 95% and 5% blue intrinsic (power), Blue: Blue Intrinsic LED 50%+50% Red Phosphor.

The blue dices of the red channel are converted into red using a phosphor layer thickness of 9 μm (using e.g. a 20 vol % dispersion of the phosphor and applying a 45 μm thick phosphor/matrix layer). The blue channel of the module can be coated with the same dispersion, but the thickness should be limited to ˜20 μm (4 μm of phosphor). This results in an LED module with the colour gamut displayed in FIG. 3, in which 50 percent of the blue power is converted to red using a thin phosphor layer.

In table 1 the increased light output of this 4-2-1 (RGB) module is illustrated with the border condition that a maximum of 1 W of electrical power is dissipated per die. Colour temperatures exceeding 4000 K cannot be obtained using the 4-2-1 configuration; a 3-2-2 configuration can be used in those cases.

TABLE 1
Light output (lm) for a module with R-G-B = 4-2-1 in which part
of the blue light is converted to red (given by % in column 1, or
color coordinate in column 2). Border condition: maximum power
of 1 W/die.

| % of blue rad. power | X (blue | CCT = | CCT = | CCT = |
|---|---|---|---|---|
| converted to red | channel) | 2700K | 3000K | 4000K |
| 0 | 0.14 | 90 lm | 96 lm | 112 lm |
| 40 | 0.27 | | | 123 lm |
| 50 | 0.31 | 103 lm | 114 lm | |
| 60 | 0.36 | 110 lm | 124 lm | |

Even in the case that the border conditions are somewhat less strict (7 W/module, 2 W/die max.), the increase in light output is still exceeding 10%.

The person skilled in the art realizes that the present invention by no means is limited to the preferred embodiments described above. On the contrary, many modifications and variations are possible within the scope of the appended claims.

1. A white light source, comprising:
at least one blue light source;
at least one green light source; and
at least one red light source;
wherein said blue light source comprises:
(i) a first light emitting diode capable of emitting light at a first wavelength, and
(ii) first wavelength-converting material arranged to absorb at least a portion of said light at said first wavelength and emit light at a second wavelength ranging from 590 nm to 750 nm, nm and wherein said portion of said light at said first wavelength comprises from 10% to 70% of a total amount of emitted light at said first wavelength.

2-3. (canceled)

4. The white light source of claim 1, wherein said portion of said light at said first wavelength comprises from 45% to 55% of a total amount of emitted light at said first wavelength.

5. The white light source of claim 1, wherein said first wavelength ranges from 400 nm to 485 nm.

6. The white light source of claim 1, wherein said first wavelength-converting material is disposed as a substantially uniform layer over said first light emitting diode.

7. The white light source of claim 6, wherein said layer of said first wavelength converting material has a thickness ranging from 1 μM to 10 μm.

8. The white light source of claim 1, wherein said first wavelength-converting material is selected from the group consisting of: YO₂S:Eu³⁺, Bi³⁺; YVO₄:Eu³⁺, Bi³⁺; SrS:Eu²⁺; SrY₂S₄:Eu²⁺; Ca La₂S₄:Ce³⁺; ZnCdS:Ag,Cl; (Ca,Sr)S:Eu²⁺; (Ca,Sr)Se:Eu²⁺; SrSi₅N₈:Eu²⁺; (Ba_{1-x-y}SrₓCa_{y})₂Si₅N₈:Eu²⁺; and (Sr_{1-x-y}CaₓBa_{y})₂Si₅₋ₓAlₓN₈₋ₓOₓ:Eu, and combinations thereof, where 0≦x≦1, 0≦y≦1, and 0≦(x+y)≦1.

9. The white light source of claim 1, wherein said green light source comprises a second light emitting diode capable of emitting light at a third wavelength, and a second wavelength-converting material arranged to absorb at least a portion of said light at said third wavelength and emit light at a fourth wavelength.

10. The white light source of claim 9, wherein said third wavelength lies in the range of 380 nm to 485 nm.

11. The white light source of claim 9, wherein said fourth wavelength lies in the range of 500 nm to less than 590 nm.

12. The white light source of claim 9, wherein said portion of said light at said third wavelength comprises at least 90% of a total amount of emitted light at said third wavelength.

13. The white light source of claim 9, wherein said second wavelength-converting material is disposed as a substantially uniform layer over said second light emitting diode.

14. The white light source of claim 13, wherein said layer of said second wavelength-converting material (3″) has a thickness ranging from 5 μm to 40 μm.

15. The white light source claim 9, wherein said second wavelength-converting material is selected from the group consisting of: ZnS:Cu,Ag; SrSi₂O₂N₂:Eu²⁺; (Sr₁₋ᵤ₋ᵥ₋ₓMgᵤCaᵥBaₓ)(Ga_{2-y-z}Al_{y}In_{z}S₄):Eu²⁺;SrGa₂S₄:Eu²⁺; (Ba₁₋ₓSrₓ)SiO₄:Eu; (Ba,Sr,Ca)SiO₄:Eu²⁺, and YAG phosphors, of and combinations thereof, where 0≦(u,v,x,y,z)≦1, 0≦(y+z)≦1, and 0≦(u+v+x)≦1.

16. The white light source of claim 1 wherein said red light source comprises a third light emitting diode capable of emitting light at a fifth wavelength, and a third wavelength-converting material arranged to absorb at least a portion of said light at said fifth wavelength and emit light at a sixth wavelength.

17. The white light source of claim 16, wherein said fifth wavelength ranges from 380 nm to 485 nm.

18. The white light source of claim 16, wherein said sixth wavelength ranges from 590 nm to 750 nm.

19. The white light source of claim 16, wherein said portion of said light at said fifth wavelength comprises at least 90% of a total amount of emitted light at said fifth wavelength.

20. The white light source of claim 16, wherein said third wavelength-converting material is disposed as a uniform layer over said third light emitting diode.

21. The white light source of claim 20, wherein said layer of said third wavelength-converting material (4″) has a thickness ranging from 5 μm to 40 μm.

22. The white light source, wherein said third wavelength-converting material is selected from the group consisting of: YO₂S:Eu³⁺, Bi³⁺; YVO₄:Eu³⁺, Bi³⁺; SrS:Eu²⁺; SrY₂S₄:Eu²⁺; CaLa₂S₄:Ce³⁺; ZnCdS:Ag,Cl; (Ca,Sr)S:Eu²⁺; (Ca,Sr)Se:Eu²⁺; SrSi₅N₈:Eu²⁺; (Ba_{1-x-y}SrₓCa_{y})₂Si₅N₈:Eu²⁺; (Sr_{1-x-y}CaₓBa_{y})₂Si₅₋ₓAlₓN₈₋ₓOₓ:Eu; YO₂S₂:Eu; and SrY₂S₄:Eu²⁺, and combinations thereof, where 0≦x≦1, 0≦y≦1, and 0≦(x+y)≦1.

23. The white light source of claim 1, wherein said green light source (3) comprises a light emitting diode emitting light at a wavelength in the range of 500 nm to less than 590 nm.

24. The white light source of claim 1, wherein said red light source comprises a light emitting diode emitting light at a wavelength in the range of 590 nm to 750 nm.

25. The white light source of claim 1, comprising one blue light source, two green light sources and four red light sources and capable of emitting white light having a colour temperature of 2700 K.

26. (canceled)

27. The white light source of claim 1, comprising two blue light sources two green light sources and three red light sources and capable of emitting white light having a colour temperature of 4000 K.

28-29. (canceled)
